(19) United States
(12) Patent Application Publication
(10) Pub. No.: US 2007/0257310 A1
(43) Pub. Date: Nov. 8, 2007

(54) Body-tied MOSFET device with strained active area

(75) Inventors: Weston Roper, Shakopee, MN (US); Eric E. Vogt, Maple Grove, MN (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc., Morristown, NJ (US)

(21) Appl. No.: 11/415,932

(22) Filed: May 2, 2006

(51) Int. Cl. H01L 27/12; H01L 21/8234; H01L 21/8238; H01L 21/336; H01L 27/01; H01L 31/0392

(52) U.S. Cl. 257/347; 438/197; 438/199

(57) ABSTRACT

A body-tied MOSFET device and method of fabrication are presented. In the method of fabrication, oxygen diffuses and reacts down a first axis of a pFET or nFET. This results in a partial oxidation of a buried-oxide/silicon island interface. The partial oxidation produces a thickness variation in the silicon island that creates a stress along the first axis. The stress along the first axis modifies a device characteristic of the FET. Oxidation along a second, perpendicular, axis may also be inhibited. The partial oxidation may be incorporated in SOI and STI based process flows. In addition, a dual-gate oxidation process may further enhance device characteristics.

### FIELD

The present invention relates generally to the field of MOSFET devices and related processing, and more particularly to a body-tied MOSFET device having a strained active area for achieving desired device characteristics.

### BACKGROUND

One issue that metal-oxide-semiconductor field effect transistors (MOSFETs) or (FETs) fabricated in a silicon-on-insulator (SOI) substrate may experience is a floating body effect. As a FET is operated, impact ionization currents deposit a charge in the FET's body. As a consequence of the body being electrically isolated, charge will accumulate there. Throughout operation, the amount of charge will vary and cause the threshold voltage of the FET to likewise vary. In some applications, this consequence is advantageous because it ultimately reduces the threshold voltage of a FET. In other applications, a body-contact directly biases the body through a body-tie, allowing certain device parameters to be tailored, such as threshold voltage and saturated drain current.

In radiation hardened (rad-hard) applications, however, the bodies cannot store a charge or be biased. Instead, rad-hard FETs—which use the insulating layer of the SOI substrate to electrically isolate their body regions—need to have their bodies grounded. Grounding the body (via a body-tie coupling to a body contact), prevents radiation induced charge from causing a FET to glitch or erroneously change state (commonly referred to as a soft error or an upset). Because the bodies are grounded, however, device parameters, like the threshold voltage, cannot be tailored.

### SUMMARY

A body-tied FET and method of fabrication are presented. The FET includes a strained silicon island. The degree of strain of the island determines the device characteristics of the FET. The island may be formed in a semiconductor substrate, such as SOI, using CMOS processing techniques. The island is located on top of a buried oxide layer and the buried oxide/island interface is oxidized to create a thickness variation, or bending, along a first axis of the island.

In order to oxidize the island along the first axis, trenches, such as shallow trench isolation (STI) trenches, are placed in close proximity to the buried oxide/island interface. Then, oxygen diffuses through these trenches and reacts at the interface. The oxygen reaction creates an oxide wedge having a profile directly attributed to the diffusion profile of the oxygen and results in a thickness variation in the island, which effectively bends it upward.

To tailor a FET, its associated island may be oxidized for a predetermined amount of time. The predetermined amount of time directly establishes the amount of strain in the island. Increasing the strain may increase mobility and decrease threshold voltage. Consequently, increased strain may ultimately increase saturated drain current (I_{DSAT}), which may improve the overall speed of a circuit.

In order to incorporate oxide/silicon interface oxidation into a CMOS process flow, several example processes are disclosed. For example, a CMOS process flow may use a dual-gate oxidation process. In such a process, a trench (e.g., an STI trench) is oxidized, etched, and re-oxidized in order to increase bending along a first axis. In one example, a mask may inhibit oxidation down a second, perpendicular axis. Depending on the type of FET, the orientations of the first and second axis may vary. For instance, to increase carrier mobility in a p-type FET, strain should be induced in an axis that is perpendicular to current flow.

After the island is strained, CMOS processing continues and a FET is formed in the island. The FET includes a gate, a source, and a drain. The FET also includes a body region (which is underneath the gate) that is coupled to a body-contact through a body-tie. In one example, the body-contact provides a ground potential to the body.

As a result, a FET may be grounded through a body-tie, and still be tailored to have specific device characteristics. In addition, some FETs, which are formed in other islands, may or may not include a strained active area. For instance, a high speed data path of a circuit may include FETs with strained islands, while other portions of the circuit may not.

These as well as other aspects and advantages will become apparent to those of ordinary skill in the art by reading the following detailed description, with reference where appropriate to the accompanying drawings. Further, it is understood that this summary is merely an example and is not intended to limit the scope of the claims.

### BRIEF DESCRIPTION OF THE DRAWINGS

Certain examples are described below in conjunction with the appended drawing figures, wherein like reference numerals refer to like elements in the various figures, and wherein:

FIG. 1 is a top view of four silicon islands separated from each other by trenches;

FIG. 2 contains frames showing cross-sections of the silicon islands of FIG. 1;

FIG. 3 is a graph of pFET mobility vs. pFET island width;

FIG. 4 is a cross-section of an island from FIG. 1 being along its width;

FIG. 5 is a cross-section of the island of FIG. 4 having overlapping oxygen diffusion regions along its width;

FIG. 6 is a graph of pFET mobility vs. stress and pFET island width;

FIG. 7 is a graph of pFET mobility vs. pFET gate length;

FIG. 8 is a graph of pFET mobility vs. stress and pFET gate length;

FIG. 9 is a cross-section of an island from FIG. 1 being bent along its length;

FIG. 10 is a cross-section of the island of FIG. 9 having overlapping oxygen diffusion regions along its length;

FIG. 11 is a flow diagram of a method of bending a silicon island; and

FIG. 12 is a cross-section of strained and un-strained FETs.

### DETAILED DESCRIPTION

### a) Oxidizing a Buried Oxide/Silicon Island Interface

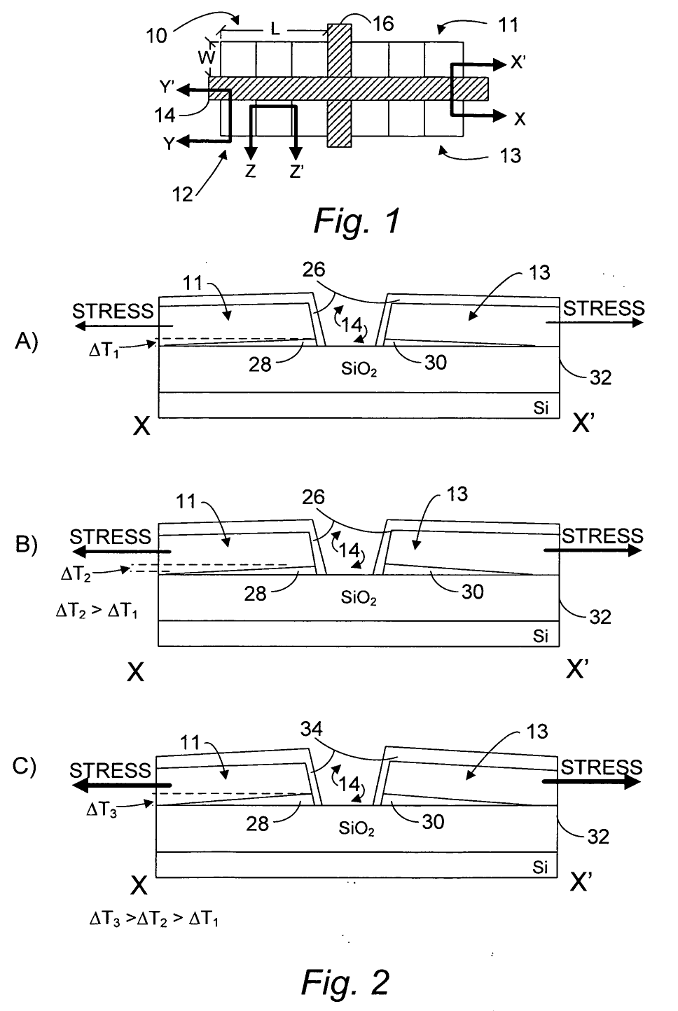

Turning now to the figures, FIG. 1 is a simplified block diagram showing a top view of four islands 10-13 located on top of an insulating layer. In most instances, the insulating layer is a buried oxide layer of an SOI substrate. Such an SOI substrate has a silicon layer located on top of the buried oxide and a bulk silicon substrate layer located below the insulating layer. Islands 10-13 may each eventually serve as an active area for a FET.

In order to provide electrical or physical isolation, trenches 14 and 16 run between islands 10-13. Trench 14 is parallel with a Length (L) of islands 10-13 and trench 16 is parallel with a Width (W) of islands 10-13. A Shallow Trench Isolation (STI) process may form trenches 14 and 16, for example (the STI process typically stops on the buried oxide). It should be understood that a variety of trenches may or may not be located in between islands 10-13. Overall, the purpose of the trenches, which will be described below, is to provide diffusion paths to a buried oxide/silicon island interface.

Generally, when an STI trench is formed (by a reactive ion etch, for example), the oxide/silicon interface is in close proximity to the STI trench (i.e., within several diffusion lengths). Because the oxide/silicon interface is within close proximity, subsequent thermally oxidative processing may cause oxide to diffuse to the oxide/silicon island interface, react, and create an oxide wedge in between a buried oxide and a silicon island. This oxide wedge effectively bends the silicon island upward and creates a stress along an axis of the silicon island. In order to demonstrate this effect, a series of frames A-C, taken from a cross-section X-X′ through islands 11 and 13, are shown in FIG. 2. Frame A is a simplified cross-section showing oxide wedge growth from a liner oxidation process and frames B and C are simplified cross-sections showing oxide wedge growth from a gate oxidation process. It should be understood that a variety of oxidation processes, in addition to liner and gate oxidation processes, may create the oxide wedges of frames A-C.

At frame A of FIG. 2, the liner oxidation process creates a liner oxide 26 that surrounds islands 11 and 13. In addition to growing liner oxide 26, the liner oxidation process also creates oxide wedges 28 and 30 in between islands 11 and 13 and a buried oxide 32. Oxide wedges 28 and 30 run parallel with the widths of islands 11 and 13 (see FIG. 1) and they grow from silicon islands 11 and 13. The diffusion that occurs at the oxide/silicon interface creates a slope in the wedges that falls towards the center of islands 11 and 13. Because the slope is attributed to the diffusion, the slope, or shape, may therefore take on a variety of forms.

Once the wedges begin to grow at the oxide silicon interface, the islands 11 and 13 begin to vary in thickness. The thickness variation across the silicon island, shown as ΔT₁, is positively correlative with a stress that is induced along the width of islands 11 and 13. In effect, the oxidation of the buried oxide/silicon island interfaces of islands 11 and 13 causes both islands to bend upward. Furthermore, subsequent oxidation processes may increase the bending by causing oxide wedges 28 and 30 to grow in thickness.

At frame B of FIG. 2, the gate oxidation process causes liner oxide 26 to grow in thickness. The thickness variation of islands 11 and 13 increases, shown as ΔT₂, and the stress along the width of islands 11 and 13 likewise increases. Because the liner oxide 26 is present during the gate oxidation, it acts as a diffusion barrier and reduces the growth rate of oxide wedge 28 and 30. If the liner oxide 26 is removed prior to the gate oxidation, more oxide will diffuse to the oxide/silicon interface and therefore grow thicker wedges 28 and 30.

At frame C, such a scenario is shown. Liner oxide 26 has been stripped and the gate oxidation process produces a gate oxide 34 which surrounds islands 11 and 13. In addition, the gate oxidation process increases the thickness of oxide wedges 28 and 30. Oxide wedges 28 and 30, in turn, produce a greater thickness variation, shown as ΔT₃, across islands 11 and 13. Because ΔT₃ is larger than ΔT₂, islands 11 and 13 bend more than they do in frame B. Accordingly, the bending induces more stress along the widths of islands 11 and 13.

By subjugating trench 14 to a cyclical treatment of etching and oxidation, oxide wedges 28 and 30 may grow to any desired thickness. A dual-gate oxidation process, for example, may provide such a cyclical treatment. Generally, dual-gate oxidation processes create at least two different gate oxide thicknesses on a common substrate. One gate oxide is thick and it is used for the gate of a high-voltage FET. The other gate is thin and it is used for the gate of a low-voltage FET.

At a first oxidative step of a dual-gate oxide process, a first oxide layer grows on top of silicon islands and it may also grow on the sidewalls of trenches (e.g., trench 14 and/or 16) that are proximal to the silicon islands. The first oxidative step, in a similar fashion to the description above, may increase a bending of the silicon islands. At a first etching step, an etch removes the first oxide layer from islands where low-voltage FETs are to be located. Then, a second oxidative step produces a thin, second oxide layer. If the etch removes the first oxide layer from the sidewalls of the trenches, the diffusing oxygen (in the second oxidative step) will not have to diffuse through oxidized sidewalls in order to reach the oxide silicon interface. Therefore, in areas where large silicon island bending is desired, the first oxide layer should be removed from the sidewalls prior to the second oxidative step.

### b) Straining a Silicon Island to Modify Device Characteristics

Bending or straining a FET's island in the above described manner will influence the performance of a FET. For example, a circuit that includes FETs having strained islands may improve the circuit's overall speed. A formula relating some device characteristics to I_{DSAT} (in saturation when V_{DS}>V_{GS}>V_{T}) is given as:
I_{DSAT}=μ*C_{OX}*W*(V_{GS}−V_{T})²/(2*L_{gate})
where V_{DS} is the drain-source bias, V_{GS} is the gate-source bias, V_{T} is the threshold voltage, μ is mobility, C_{OX} is gate oxide capacitance, W is the width of a FET, and L_{gate} is the gate length.

In general, the larger a FET's I_{DSAT}, the faster a circuit using the FET will be. A large I_{DSAT} will allow downstream circuits to charge and switch at an increased rate. To increase I_{DSAT}, any one of the device parameters above may be modified. For instance, decreasing the threshold voltage will increase I_{DSAT}. On the other hand, increasing mobility will increase I_{DSAT}.

Typically, increased stress decreases the threshold voltage of a FET. This occurs because the semiconductor work function of the FET is directly proportional to island strain. Increasing island strain, decreases the work function and therefore, decreases the voltage needed to invert a channel region of the FET. Thus, to create a desired threshold voltage, the buried oxide/island interface of the FET's island should be oxidized for the appropriate amount of time that it will take to achieve the desired threshold voltage.

### b) Straining a Silicon Island to Modify Mobility

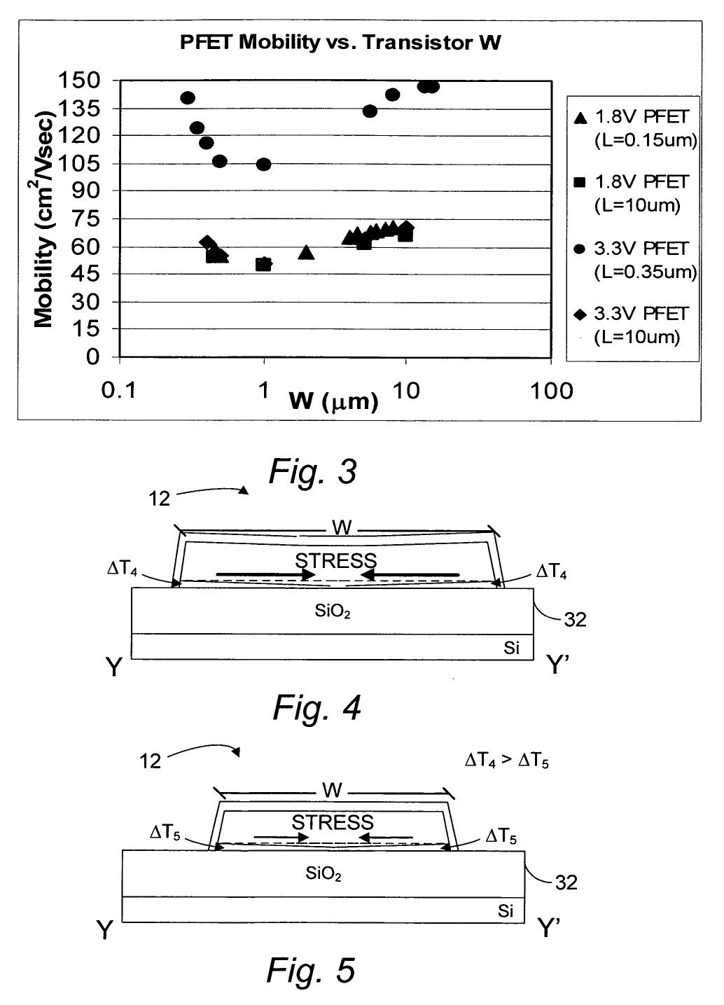

In a similar manner, other device parameters may be modified. One such parameter is mobility. FIGS. 3-11 show in more detail how mobility may be enhanced by island strain. First, FIG. 3 is a graph that plots mobility versus channel width for a variety of pFETs that have an oxidized buried oxide/island interface. FIG. 3 shows that as the pFETs' widths decrease (until about 1 μm) the mobility of the pFETs likewise decreases. This is because as the widths decrease, the thickness variation occurs over a larger percentage of the width of a FET. For example, in FIG. 4 a cross section Y-Y′ (taken from FIG. 1) shows that as width decreases, the thickness variation ΔT₄ moves towards the center of island 12 and island bending increases. However, overlapping thickness variations, shown in FIG. 5, relieve stress as the thickness variation ΔT₅ is reduced and bending decreases. This explains why the pFETs having sub-micron widths, shown in FIG. 3, begin to increase in mobility.

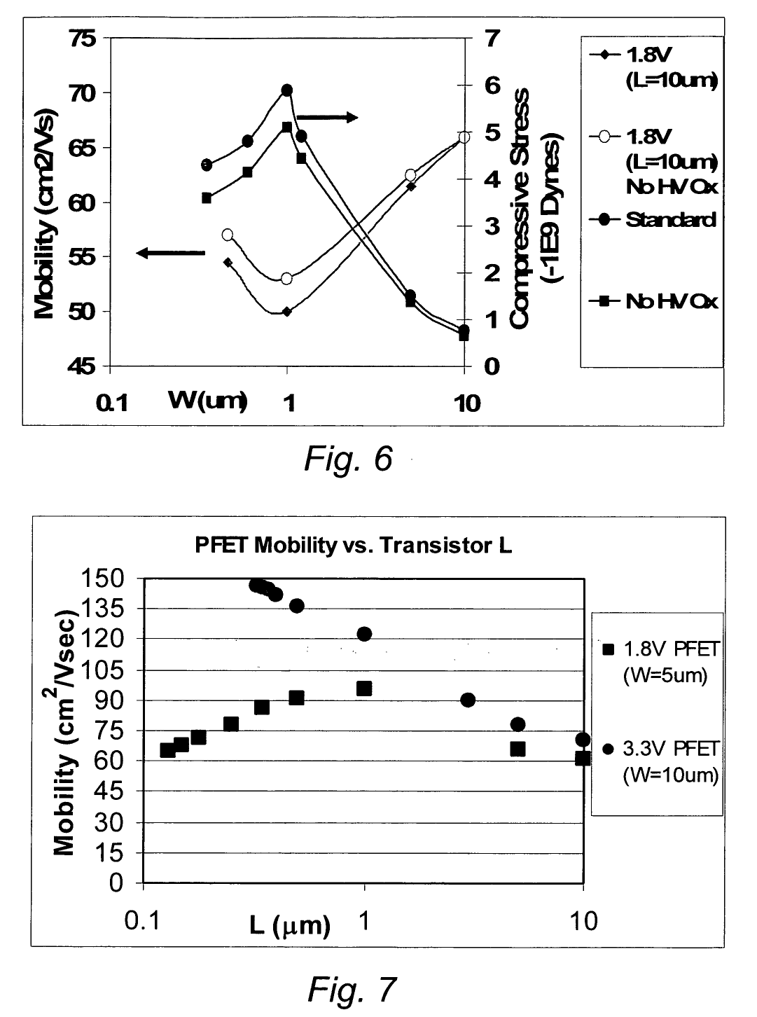

To reinforce this overlap concept, FIG. 6 is a graph illustrating predicted stress (using SUPREM 4 simulations) and mobility vs. width for various pFETs. As a pFET's width decreases to 1 μm, stress increases and mobility decreases. As the widths move past 1 μm and towards the sub-micron regime, stress decreases and mobility increases. Again, in the sub-micron regime, the overlapping oxide diffusions underneath a silicon island relieve island bending and stress. The significance of this effect will be discussed further with reference to FIGS. 7-10.

Returning to FIG. 3, one sole pFET has a higher mobility than the other pFETs. Evidently, stress along the width of a pFETs is not the only factor that determines mobility. This sole pFET, it turns out, has an optimal island bending along its length. In fact, what will be described below is that stress along the length of a pFET increases mobility. Moreover, depending on the type of FET an island is located in, island bending along a preferred axis increases mobility.

To demonstrate this stress effect, FIG. 7 is a graph of pFET mobility vs. various gate lengths. As gate length (and overall transistor length) decreases, mobility increases (until a gate length of about 1 μm). However, the high-voltage (3.3 V) pFET continues to increase in mobility as it overtakes 1 μm and enters the sub-micron regime. The low-voltage pFET (1.8V) begins to decrease in mobility when it enters the sub-micron regime. It is believed that the mobility decrease of the low-voltage pFET is due to an aggressive halo implant to roll the low-voltage pFET device threshold up. This effectively increases the vertical electric field at gmmax, which reduces mobility. Because the source and drains contribute at least 0.8 μm to the overall transistor length, the mobility decrease is not attributed to an overlap of the oxidation at the buried oxide/silicon island interface, as described with reference to FIGS. 3-4.

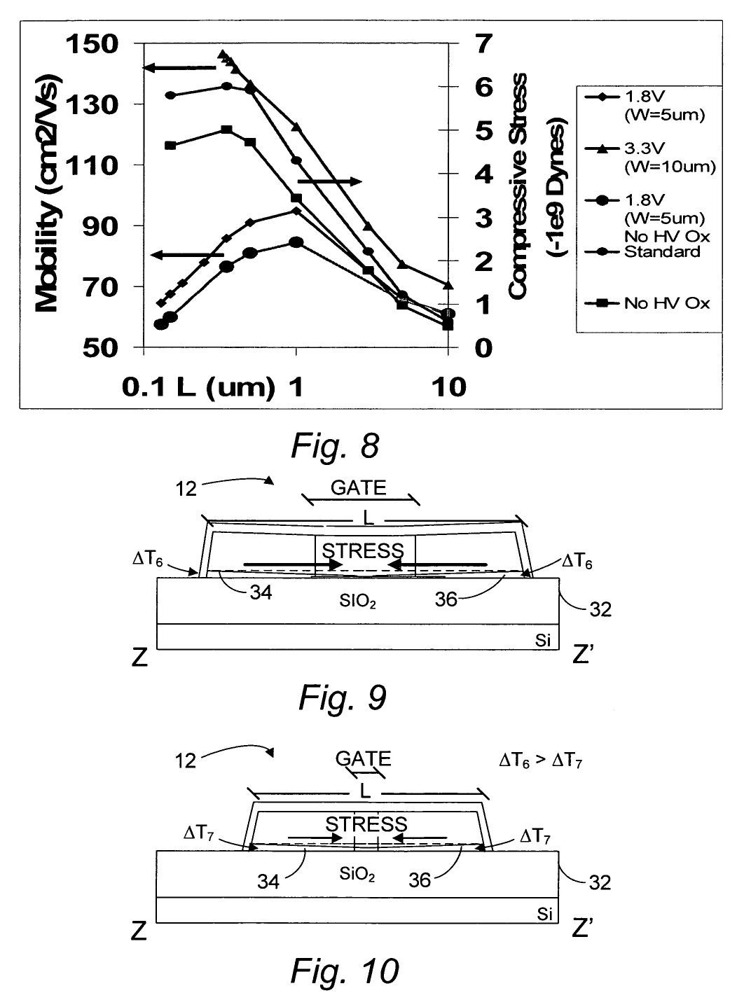

As an additional example, FIG. 8 is a graph plotting simulated stress and mobility vs. gate length for a variety of pFETs. In this example, the low-voltage (1.8V) pFETs exhibit a mobility decrease in the sub-micron regime. The high voltage and standard process pFETs, however, continue to increase in mobility well into the sub-micron regime. Again, the decrease in mobility observed in some of the pFETs is likely due to halo implants and not an overlap of oxide diffusion regions under a silicon island.

Generally, as the island bending increases and the length of a pFET decreases, stress moves towards the center of the pFET (and under a gate). To demonstrate this, FIG. 9 is a cross section Z-Z′, taken from FIG. 1, along the length of island 12. In FIG. 9, an oxidative step has created wedges 34 and 36. Wedges 34 and 36 bend island 12 upwards. A thickness variation, indicated by ΔT₆, induces a stress along the length of the island 12. As shown in FIG. 10, if the overall island length enters the sub-micron regime, oxide wedges 34 and 36 will overlap and the overall thickness variation, indicated by ΔT₇, will decrease. As a result of such a decrease, the stress along the length of FET 12 will decrease and so will carrier mobility that is along the length of island 12.

Overall, to bend a silicon island for a mobility improvement, the island should be bent so that stress is promoted along one axis and inhibited along another. In particular, for a silicon island in a pFET, stress should be promoted along the length of the pFET and inhibited along the width. The contrary is true for a silicon island in an nFET. That is, stress should be promoted along the width of the nFET and inhibited along the length.

### e) A Method of Straining a Silicon Island to Modify Device Parameters

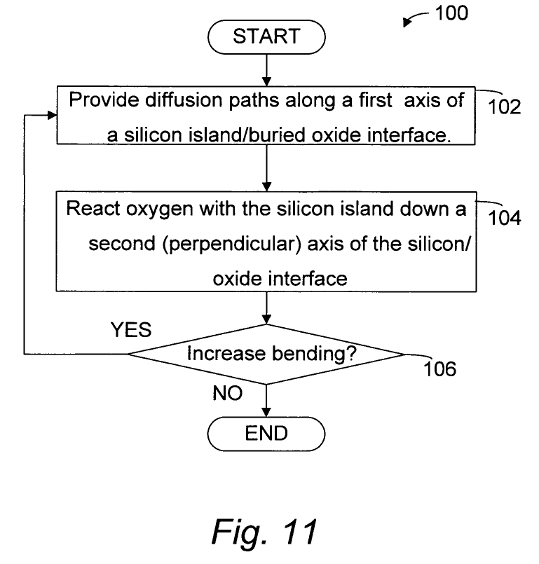

A method 100 of straining a silicon island is presented in FIG. 11. By application of method 100, island bending may modify and improve a FET's device characteristics. In addition, island bending along a preferred axis may yield an enhanced mobility in a FET. At block 102 of method 100, diffusion paths are provided along a first axis of a silicon island/buried oxide interface. If the silicon island is located in a pFET, the first axis may be along the width of the pFET. Alternatively, if the silicon island is located in an nFET, the first axis may be along the length of the nFET. In either case, an etching step may create trenches (such as STI trenches) that flank the island and consequently provide diffusion paths. These trenches should be located in close proximity to a buried oxide/silicon island so that during an oxidative step, oxygen does not encounter a significant diffusion barrier.

Once the diffusion paths are provided, oxygen diffuses to the oxide/silicon interface and reacts with the island along a second (perpendicular) axis, shown at block 104. As a result, the island bends and induces a stress along the second axis. If the island is in a pFET, the second axis may be parallel to the length of the island. If the island is in an nFET, the second axis may be parallel to the width of the island.

In order for oxygen to diffuse and react at the oxide/silicon interface, a variety of oxidative processes may be used. As described above, these processes include gate oxidations, dual-gate oxidations, liner oxidations, annealing steps, etc. It should be understood that the method 100 is not limited to the types of oxidative steps that are used.

After the oxygen reaction, the bending of the island can be increased, or method 100 may be completed, as shown at decision block 106. If the bending is to be increased, diffusion paths are once again provided along the first axis of the silicon/oxide interface. This may simply include etching oxide that formed in the trenches at block 104 and thus reducing the distance through which the oxygen diffuses until it reaches the oxide/silicon interface.

Although method 100 allows for oxidation along the second axis, additional measures may be taken to prevent oxidation down the first axis. A hard mask, for example, may prevent diffusion of oxygen to the oxide/silicon interface in a direction that is parallel with the first axis. Alternatively, by simply not forming trenches that flank a second axis of the island, oxygen diffusion down the first axis may also be inhibited.

### e) Selectively Straining FETs Located on a Common Substrate

Overall, a variety of FETs and other related devices may be modified and optimized via oxidation at the buried oxide/island interface. In particular, one type of FET that may benefit from the strain is a body-tied FET. Body-tied FETs are common in rad-hard applications. To prevent soft-errors and other types of upsets due to radiation events, the body region under the gate of the FET is grounded. This is commonly done via a body-tie coupled to a body-contact.

Advantageously, some FETs within a circuit may include a strained island while others may not. For instance, some portions of a circuit may require a fast switching speed, which requires a high I_{DSAT}. FETs within this portion of the circuit, or in a particular data path, may have an increased oxidation of the buried oxide/island interface (relative to other FETs within the circuit). The increased oxidation, for instance, may increase mobility and decrease threshold voltage resulting in an increased I_{DSAT}.

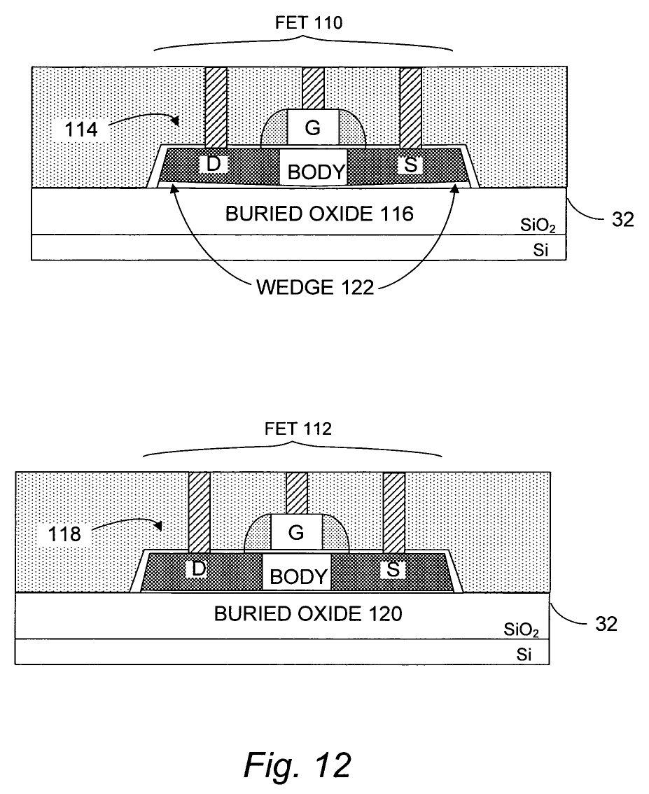

As an example, FIG. 12 shows two FETs 110 and 112. FET 110 includes an island 114 located on top of a buried oxide 116 and FET 112 includes an island 118 located on top of an buried oxide 120 (both islands includes a source, a drain, and a body). FET 10's island is strained by an oxide wedge 122 that has been grown in between buried oxide 116 and island 114. FET 112's island, on the other hand is not strained, and a relatively thin oxide that exists between island 118 and buried oxide 120.

In some instances, although lowering the threshold voltage increases I_{DSAT}, it may also increase off state leakage currents. Therefore, by selectively oxidizing islands, a balance between off-state leakage currents and speed may be achieved. It is also contemplated that a circuit may contain some islands are more oxidized than others. As a result, instead of biasing a FET's body to achieve a desired device characteristic, island strain is used to tailor the device characteristics.

### f) Conclusion

The presented methods for bending a silicon island, when carried out, modify device characteristics of a FET. Although only a handful of oxidative, etching, and other processing steps have been described, it should be understood that the described methods may be undertaken using a variety of alternative processing steps. Also, additional structures may be added or removed to enhance island bending. For example, by increasing the number of contact fingers in the source or drain regions, island bending may be modified. More contact fingers added along one axis may decrease bending. Likewise, using only one contact finger may optimize bending.

Although the benefits of straining an island may be particularly useful in radiation hardened applications, and in particular body-tied FETs, other FETs or alternative structures, such as other types of micro-electronic devices may benefit from island bending.

It should be understood, therefore, that the illustrated examples are examples only and should not be taken as limiting the scope of the present invention. The claims should not be read as limited to the described order or elements unless stated to that effect. Therefore, all examples that come within the scope and spirit of the following claims and equivalents thereto are claimed as the invention.

We claim:

1. A method for modifying a device characteristic of a MOSFET relative to a device characteristic of another MOSFET, the method comprising:
providing first and second silicon islands, wherein the first island is flanked by first and second trenches along a first axis;
diffusing oxygen through the first and second trenches to a buried oxide interface below the first silicon island, thereby causing a first oxidation of the first silicon island that increases strain along a second axis; and
forming a first MOSFET in the first silicon island and a second MOSFET in the second silicon island, wherein the first MOSFET has a device characteristic that is modified by the increased strain.

2. The method as in claim 1, wherein diffusing the oxygen further comprises:
diffusing the oxygen for a predetermined amount of time, wherein the predetermined amount of time establishes a desired strain.

3. The method as in claim 3, wherein the desired strain results in a desired saturated drain current characteristic of the first MOSFET.

4. The method as in claim 1, wherein the first and second MOSFETs are each body-tied so that a body region under a gate of each MOSFET is grounded.

5. The method as in claim 4, wherein the device characteristic is threshold voltage, and wherein the threshold voltage is negatively correlative with the increased strain.

6. The method as in claim 4, wherein the device characteristic is carrier mobility, and wherein the carrier mobility is positively correlative with the increased strain.

7. The method as in claim 1, wherein diffusing oxygen through the first and second trenches further comprises:
inhibiting oxide diffusion to a buried oxide interface below the second silicon island, thereby preventing an oxidation of the second silicon island.

8. The method as in claim 1, wherein the first axis is perpendicular to the second axis.

9. The method as in claim 1, wherein the increased strain is attributed to a thickness variation in a silicon dioxide layer that is produced as a result of the oxidation of the first silicon island.

10. The method as in claim 9, wherein the thickness variation is centered under a gate of the MOSFET.

11. The method as in claim 1, further comprising:
to further increase strain along the second axis:
removing oxide from sidewalls of the first and second trenches, wherein the oxide is produced from the first oxidation; and
diffusing oxygen through the first and second trenches to the buried oxide interface below the first silicon island, thereby causing a second oxidation of the first silicon island that further increases strain along the second axis.

12. The method as in claim 1, wherein the first and second trenches are Shallow Trench Isolation (STI) trenches.

13. A body-tied MOSFET, comprising:
a strained silicon island located on top of a buried oxide, wherein the island is strained by an oxidation at a buried oxide/island interface in order to establish a device characteristic of the MOSFET;
a body-contact for receiving a ground potential; and
a body-tie that provides a coupling from the body-contact to a body region of the silicon island.

14. The MOSFET as in claim 13, wherein the oxidation has a variable thickness that establishes an amount of strain of the island.

15. The MOSFET as in claim 13, wherein the ground potential and the buried oxide mitigate radiation effects.

16. The MOSFET as in claim 13, wherein the device characteristic is a saturated drain current of the MOSFET.

17. The MOSFET as in claim 13, wherein the device characteristic is carrier mobility.

18. The MOSFET as claim 13, wherein the device characteristic is threshold voltage.

19. The MOSFET as in claim 13, wherein the island is fabricated in a Silicon-On-Insulator (SOI) substrate having a device layer located on top of an insulating layer, wherein the island is formed in the device layer and the buried oxide is the insulating layer.
